(19) United States
(12) Patent Application Publication
(10) Pub. No.: US 2007/0120185 A1
(43) Pub. Date: May 31, 2007

(54) Semiconductor device manufacturing method and semiconductor device

(76) Inventors: Toshiaki Komukai, Kawasaki-Shi (JP); Hideaki Harakawa, Kawasaki-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/447,880

(22) Filed: Jun. 7, 2006

(30) Foreign Application Priority Data
Nov. 28, 2005 (JP) 2005-341607

(51) Int. Cl. H01L 29/76

(52) U.S. Cl. 257/339

(57) ABSTRACT

A method for manufacturing a semiconductor device includes forming an isolation region on a semiconductor substrate; forming an impurity diffusion layer in a region which includes an end of an active area adjacent to the isolation region; depositing a metal film on the semiconductor substrate; removing at least part of the metal film on the isolation region; and subjecting the metal film and the semiconductor substrate to a heat treatment, thereby forming a silicide film on the impurity diffusion layer in a self-aligned fashion.

### CROSS-REFERENCE TO RELATED APPLICATION

This application is based upon and claims the benefit of priority from the prior Japanese Patent Applications No. 2005-341607, filed on Nov. 28, 2005, the entire contents of which are incorporated herein by reference.

### BACKGROUND OF THE INVENTION

1. Field of the Invention

The present invention provides a semiconductor device manufacturing method and a semiconductor device.

2. Related Art

A metal silicide film is formed by depositing a metal film on a semiconductor substrate and then producing a thermal reaction between the semiconductor substrate and the metal film. A STI (Shallow Trench Isolation) structure and a sidewall of a gate electrode are formed by an insulating film such as a silicon oxide film or a silicon nitride film. Due to this, the metal silicide film is not formed on the STI structure and the sidewall but the metal film is left thereon as it is. On the other hand, in a region of an active area in which region the metal film is deposited on the semiconductor substrate consisting of silicon or the like, the metal silicide film is formed by producing a reaction between the metal film and the semiconductor substrate. Thereafter, an unreacted metal film on the STI structure and the sidewall is removed, whereby the metal silicide film can be formed on the active area in a self-aligned fashion.

However, on a boundary between the STI structure and the active area, excessive metal on the STI structure is diffused into the active area and reacted with the semiconductor substrate in the active area. As a result, the metal silicide film is locally thicker on ends of the active area. If being locally thicker, the metal silicide film may penetrate an impurity diffusion layer formed in the active area. This disadvantageously deteriorates a resistance of an NP junction or a PN junction between the impurity diffusion layer and the semiconductor substrate, resulting in an increase of a standby leakage current carried across the MISFET. Furthermore, this may deactivate the MISFET.

### SUMMARY OF THE INVENTION

A method for manufacturing a semiconductor device according to an embodiment of the present invention comprises forming an isolation region on a semiconductor substrate; forming an impurity diffusion layer in a region which includes an end of an active area adjacent to the isolation region; depositing a metal film on the semiconductor substrate; removing at least part of the metal film on the isolation region; and subjecting the metal film and the semiconductor substrate to a heat treatment, thereby forming a silicide film on the impurity diffusion layer in a self-aligned fashion.

A semiconductor device according to an embodiment of the present invention comprises a semiconductor substrate; an isolation region formed into a lattice on a surface of the semiconductor substrate; an active area adjacent to the isolation region and surrounded by the isolation region; an impurity diffusion layer provided in a region which includes an end of the active area; and a silicide film provided on the impurity diffusion layer, wherein the silicide film on the end of the active area is equal in thickness to the silicide film in a central portion of the active area, and a ratio of an area of the active area to a chip area of the semiconductor device is less than 17.6%.

A semiconductor device according to an embodiment of the present invention comprises a semiconductor substrate; an isolation region formed into stripes on a surface of the semiconductor substrate; an active area adjacent to the isolation region; an impurity diffusion layer provided in a region which includes an end of the active area; and a silicide film provided on the impurity diffusion layer, wherein the silicide film on the end of the active area is equal in thickness to the silicide film in a central portion of the active area, and a ratio of an area of the active area to a chip area of the semiconductor device is less than 14%.

### BRIEF DESCRIPTION OF THE DRAWINGS

FIG. 1 is a cross-sectional view of a semiconductor device according to a first embodiment of the present invention for;

FIG. 2 is a cross-sectional view showing a method for manufacturing the semiconductor device following FIG. 1;

FIG. 3 is a cross-sectional view showing a method for manufacturing the semiconductor device following FIG. 2;

FIG. 4 is a cross-sectional view showing a method for manufacturing the semiconductor device following FIG. 3;

FIG. 5 is a cross-sectional view showing a method for manufacturing the semiconductor device following FIG. 4;

FIG. 6 is an enlarged cross-sectional view of a broken-line frame C part shown in FIG. 5;

FIG. 7 is a plan view of a TEG including an island-like active area AA and formed to examine the relationship between the STI structure 20 and the active area AA according to this embodiment;

FIG. 8 is a cross-sectional view of the TEG taken along a line 8-8 of FIG. 7;

FIG. 9 is a graph of a result of measuring the leakage current carried between the contact C and the silicon substrate 10 using the TEG shown in FIGS. 7 and 8; and

FIG. 10 is a plan view of a TEG including a stripe active area AA and formed to examine the relationship between the STI structure 20 and the active area AA according to a second embodiment of the present invention.

### DETAILED DESCRIPTION OF THE INVENTION

Hereafter, embodiments of the present invention will be explained with reference to the drawings. Note that the invention is not limited to the embodiments.

### FIRST EMBODIMENT

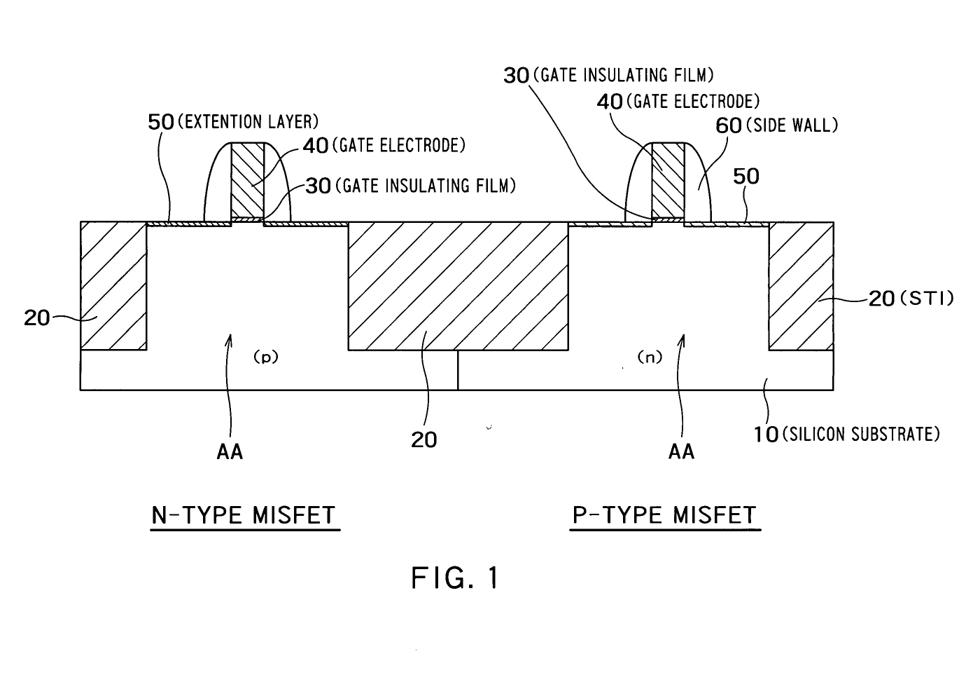

FIGS. 1 to 5 are cross-sectional views of a semiconductor device according to a first embodiment of the present invention for showing a flow of a method for manufacturing the semiconductor device. First, an STI structure 20 serving as an isolation region is formed on a silicon substrate 10. To form the STI structure 20, a known method may be used. By forming the STI structure 20, an active area AA used to form elements is defined. The active area AA is adjacent to the STI structure 20. A gate insulating film 30 is then formed on the active area AA. The gate insulating film 30 is a silicon oxide film or a film consisting of a high dielectric material higher in dielectric constant than the silicon oxide film. A gate electrode 40 is formed on the gate insulating film 30. The gate electrode 40 consists of, for example, polysilicon. As (Arsenic) ions are implanted into the silicon substrate 10 in an N-type MISFET region whereas BF₂ (Boron) ions are implanted into the silicon substrate 10 in a P-type MISFET region. By doing so, an extension layer 50 is formed in a source/drain layer region. It is noted that the N-type MISFET is formed on a P-type substrate or a P-type well, and that the P-type MISFET is formed on an N-type substrate or an N-type well. Furthermore, sidewall spacers 60 are formed on side surfaces of the gate electrode 40. As a result, a structure shown in FIG. 1 is obtained.

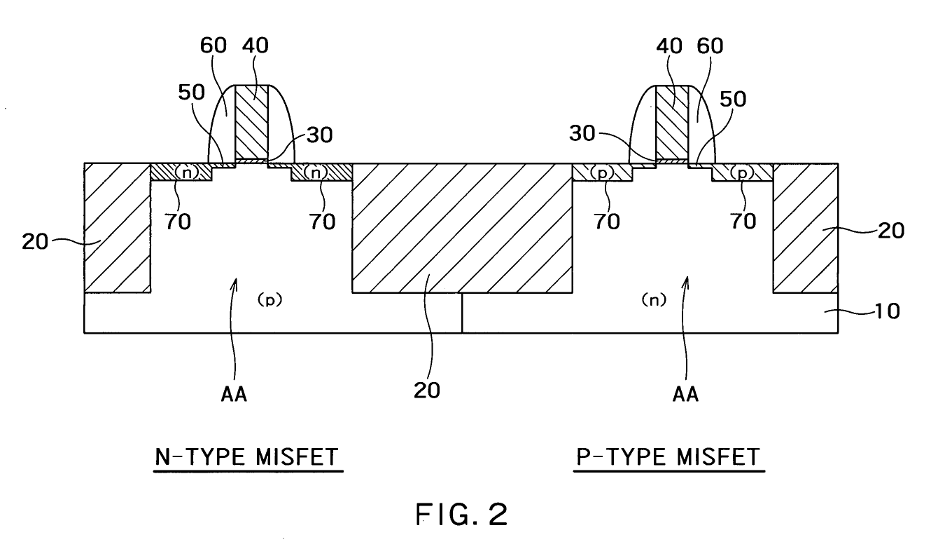

As shown in FIG. 2, using the gate electrode 40 and the sidewall spacers 60 as a mask, P (Phosphorus) ions are implanted into the silicon substrate 10 in the N-type MISFET region and B (Boron) ions are implanted into the silicon substrate 10 in the P type MISFET region. The silicon substrate 10 is then subjected to a heat treatment using RTP (Rapid Thermal Annealing). As a result, a source/drain layer 70 serving as an impurity diffusion layer is formed in the active area AA as shown in FIG. 2. The source/drain layer 70 functions as a contact region for a source/drain electrode. A PN junction or an NP junction is formed between the source/drain layer 70 and the silicon substrate 10.

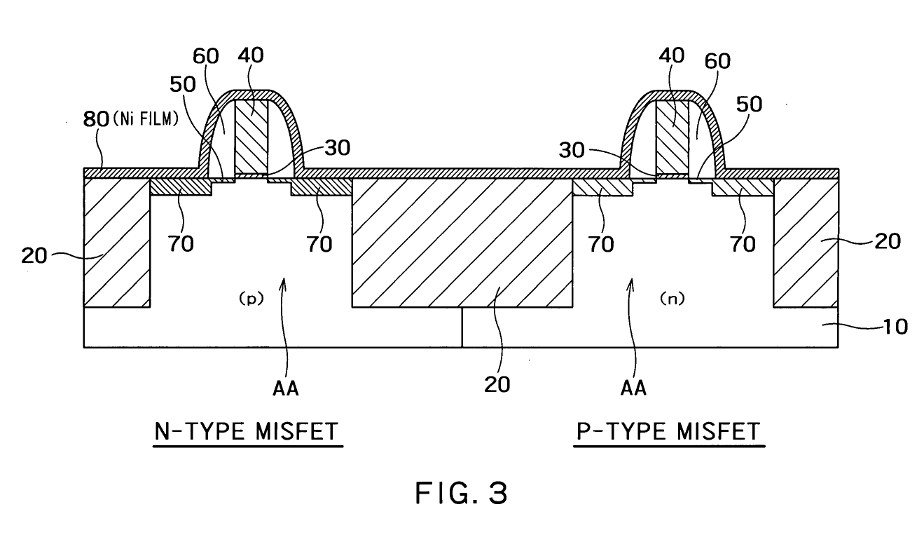

As a pretreatment, a DHF (Diluted Hydrofluoric Acid) treatment is carried out on the substrate 10, thereby removing the chemical oxide film on the silicon substrate 10. As shown in FIG. 3, a nickel film 80 is deposited as a metal film using DC (Direct Current) sputtering. The nickel film 80 has a thickness of about 8 nm.

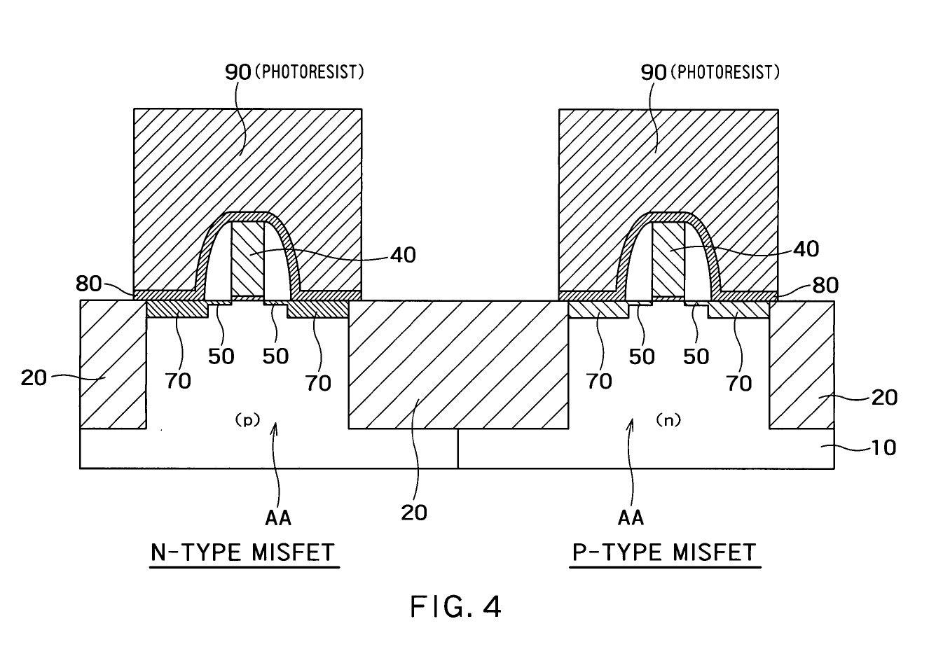

Thereafter, as shown in FIG. 4, a resist pattern (photoresist) 90 is formed on the nickel film 80 in the active area AA using lithography. Using the resist pattern 90 as a mask, the nickel film 80 on the STI structure 20 is etched away by the RIE using chlorine-containing gas. At this moment, the nickel film 80 on the STI structure 20 may be removed either entirely or partially. In this embodiment, the RIE technique using the chlorine-containing gas has been adopted by way of example. As long as a selectivity of the nickel film 80 to the photoresist 90 can be maintained, a wet etching or the like may be adopted. The photoresist 90 is then removed by a wet etching using organic chemicals without etching the nickel film 80.

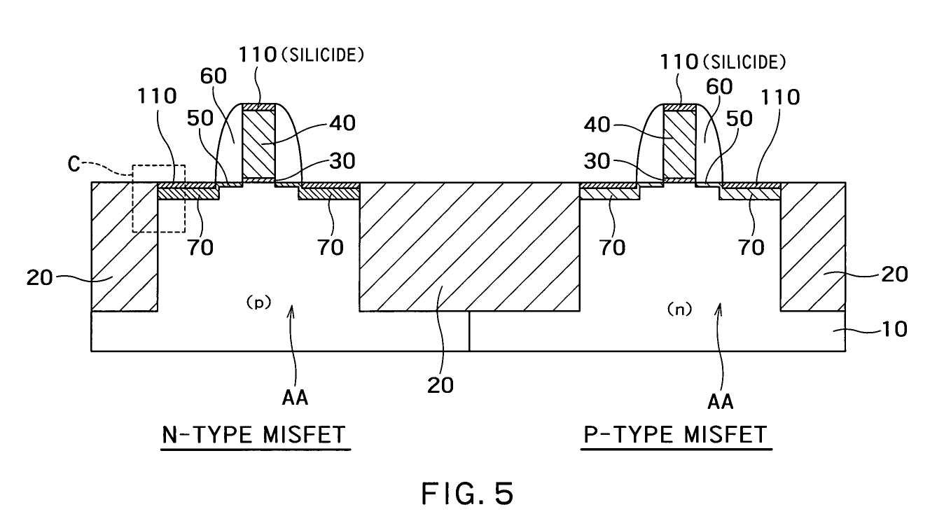

Using the RTP technique, the silicon substrate 10 is subjected to a heat treatment at a temperature of 500° C. under a nitrogen atmosphere. As a result, a thermal reaction between the silicon substrate 10 and the nickel film 80 occurs as shown in FIG. 5, whereby a nickel silicide 110 is formed on the source/drain layer 70 in the active area AA. In addition, a thermal reaction occurs between the gate electrode 40 and the nickel film 80, whereby the nickel silicide 110 is also formed on the gate electrode 40. The silicon substrate 10 is then exposed to a sulfuric acid-hydrogen peroxide mixture (SPM), thereby removing an unreacted nickel film 80 remaining on the STI structures 20 and the sidewall spacers 60. As a result, the nickel silicide 110 is formed only on the silicon substrate 10 and on the gate electrode 40 in a self-aligned fashion.

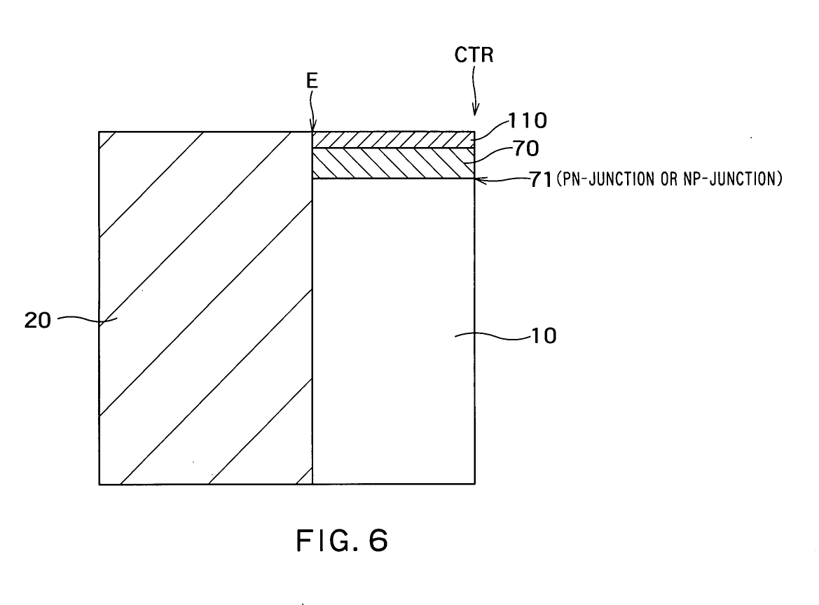

FIG. 6 is an enlarged cross-sectional view of a broken-line frame C part shown in FIG. 5. It should be noted that the nickel film 80 on the STI structure 20 is removed in advance at the above steps. Because of the removal of the nickel film 80 on the STI structure 20 in advance, nickel is not diffused into the active area AA during the heat treatment for forming the nickel silicide 110. Due to this, as shown in FIG. 6, the nickel silicide 110 on an end E of the active area AA is substantially equal in thickness to that in a central portion CTR of the active area AA. Namely, according to this embodiment, the nickel silicide 110 having a uniform thickness can be formed. As a consequence, the semiconductor device according to this embodiment can prevent the nickel silicide 110 from penetrating the NP junction or PN junction, and thereby suppress deterioration in the resistance of the NP junction or PN junction.

In this embodiment, the nickel film 80 is used as the metal film. Alternatively, a Ti (Titanium), Co (Cobalt), Ta (Tantalum), Pd (Palladium) or Pt (Platinum) film may be used as the metal film.

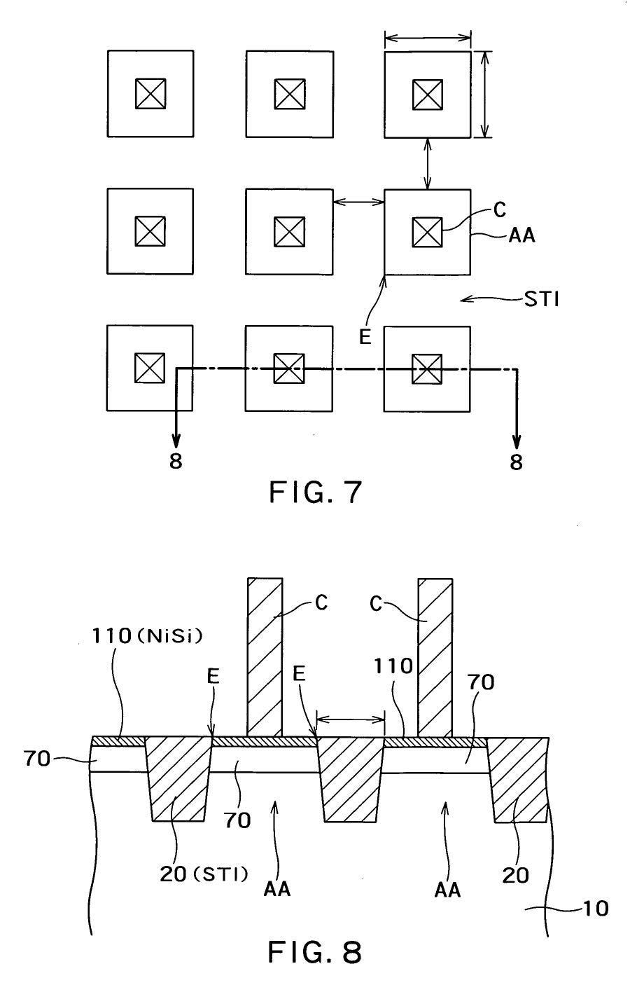

FIG. 7 is a plan view of a TEG (Test Element Group) including an island-like active area AA and formed to examine the relationship between the STI structure 20 and the active area AA according to this embodiment. A cross section of an actual semiconductor device may be equal to that shown in FIG. 5. Therefore, the semiconductor device according to this embodiment includes the silicon substrate 10, the STI structure 20 provided on the silicon substrate 10, the active area AA adjacent to the STI structure 20, the gate insulating film 30 provided on the active area AA, the gate electrode 40 provided on the gate insulating film 30, the source/drain layer 70 provided in the active area AA, and the nickel silicide 110 provided on the source/drain layer 70, as shown in FIG. 5.

The STI structure 20 is formed into a lattice on a surface of the silicon substrate 10. The active area AA is surrounded with the STI structure 20. Since this semiconductor device is formed by the above-stated manufacturing method, the nickel suicide 110 on the end E of the active area AA is substantially equal in thickness to that in the central portion CTR thereof. A contact C is formed in the central portion of each active area AA shown in FIG. 7. The contact C is provided to measure a leakage current carried across the PN junction or NP junction.

In this TEG, a size of the STI structure 20 is, for example, 1.5 μm by 1.5 μm. A width of the STI structure 20 is, for example, one of 0.14 μm, 0.16 μm, 0.18 μm, 0.20 μm, 0.22 μm, and 0.50 μm. A size of the contact C is, for example, 0.22 μm by 0.22 μm. The source/drain layer 70 is formed by implanting boron (B) ions having a concentration of 3.0×10¹⁵ cm² into the silicon substrate 10 at an energy of 3 keV, and then performing spike-annealing at 1050° C. The thickness of the nickel film 80 is about 30 nm.

FIG. 8 is a cross-sectional view of the TEG taken along a line 8-8 of FIG. 7. Each contact C is connected to the nickel silicide 110 provided on the diffusion layer 70. Using the TEG thus configured, the leakage current carried between the contact C and the silicon substrate 10 is examined.

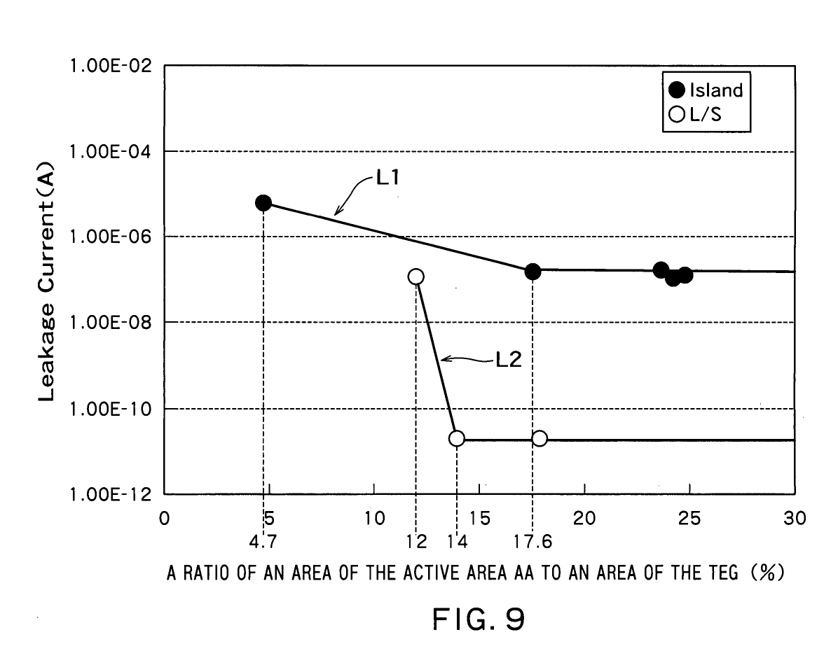

FIG. 9 is a graph of a result of measuring the leakage current carried between the contact C and the silicon substrate 10 using the TEG shown in FIGS. 7 and 8. In FIG. 9, a vertical axis indicates the leakage current and a horizontal axis indicates a ratio of an area of the active area AA to an area of the TEG. Considering an ordinary semiconductor device, it may be paraphrased the horizontal axis indicates the ratio of the area of the active area AA to a chip area of the semiconductor device. In FIG. 9, a line L1 relates to the P-type MISFET according to this embodiment. As for the N-type MISFET, since the increase of the leakage current is not recognized in the N-type MISFET, a line relating to the N-type MISFET is not shown in the graph of FIG. 9.

The inventor of the present invention discovered that this leakage current depends on the ratio of the area of the active area AA to the chip area (or the ratio of an area of the STI structure 20 to the chip area). This graph shows that if the area ratio of the active areas AA is below about 17.6%, the leakage current increases. If the area ratio of the active area AA is equal to or higher than about 17.6%, the increase of the leakage current is suppressed. The reason is as follows. If the area ratio of the active area AA is below about 17.6%, nickel on the STI structure 20 flows into ends of the active area AA during a silicidation process. As a result, the nickel silicide 110 penetrates the source/drain layer 70.

Considering these, if the area ratio of the active area AA is less than about 17.6%, the nickel film 80 present on the STI structure 20 for the silicidation is removed. In the silicidation process, an amount of nickel flowing into the ends of the active area AA is thereby restricted. It is, therefore, possible to suppress the nickel silicide 110 from penetrating the source/drain layer 70. As a result, the increase of the leakage current can be suppressed.

As can be understood, if the area ratio of the island-like active areas AA is less than about 17.6%, the nickel film 80 on the STI structure 20 is removed. Accordingly, the inventor of the present invention successfully prevented the deterioration in the resistance of the NP junction or PN junction between the source/drain layer 70 and the semiconductor substrate 10, and suppressed the standby leakage current.

### SECOND EMBODIMENT

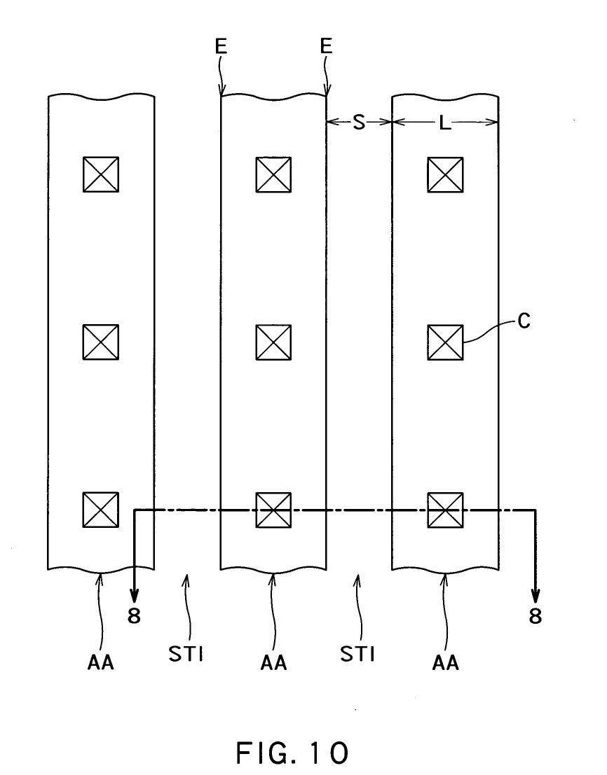

FIG. 10 is a plan view of a TEG including a stripe active area AA and formed to examine the relationship between the STI structure 20 and the active area AA according to a second embodiment of the present invention. In the second embodiment, the STI structure 20 and the active area AA are formed into stripes. The other configurations of the second embodiment may be the same as those of the first embodiment. A cross section of an actual semiconductor deice may be the same as that shown in FIG. 5.

The semiconductor device according to the second embodiment is formed by the manufacturing method already stated above. Therefore, the nickel silicide 110 on the end E of the active area AA is substantially equal in thickness to that in the central portion thereof. In the central portion of the active area AA shown in FIG. 10, the contact C is provided. The contact C is provided to measure a leakage current carried across the PN junction or NP junction.

It is assumed that a width of the active area AA is a line L and a width of the STI structure 20 is a space S. If the line L is made thicker, the ratio of the area of the active area AA to the chip area of the semiconductor device is higher. Conversely, if the line L is made thinner, the area ratio of the active area A is lower.

The width of the active area AA is, for example, one of 0.14 μm, 0.16 μm, and 0.22 μm. The width of the STI structure 20 is, for example, 1.0 μm. The source/drain layer 70 in the P-type MISFET is formed by implanting boron (B) ions having a concentration of 3×10¹⁵ cm⁻² at an energy of 4 keV, and then performing spike-annealing at 1050° C. The source/drain layer 70 in the N-type MISFET is formed by implanting phosphorus (P) ions having a concentration of 3×10¹⁵ cm⁻² at an energy of 5 keV, and then performing spike-annealing at 1050° C. The thickness of the nickel film 80 is 12 nm.

A line L2 shown in the graph of FIG. 9 depicts a result relating to the P-type MISFET and the N-type MISFET according to the second embodiment. The inventor of the present invention discovered that the leakage current depends on the ratio of the area of the active area AA to the chip area (or the ratio of the area of the STI structure 20 to the chip area) even if the active area AA is formed into stripes.

With reference to the graph of FIG. 9, it is found that if the area ratio of the active area AA is below about 40%, the leakage current increases. If the area ratio of the active area AA is equal to or higher than about 14%, the increase of the leakage current is suppressed. The reason is as follows. If the area ratio of the active areas AA is below about 14%, then nickel on the STI structures 20 flows into the ends of the active areas AA, and this makes the nickel suicide 110 penetrate the source/drain layer 70.

If the area ratio of the active area AA is less than about 14%, the nickel film 80 present on the STI structure 20 for silicidation is removed. By doing so, the amount of the nickel flowing into the ends of the active areas AA during the silicidation process is restricted. It is, therefore, possible to suppress the nickel silicide 110 from penetrating the source/drain layer 70. As a result, the increase of the leakage current can be suppressed.

As can be understood, if the area ratio of the stripe active area AA is less than about 14%, the nickel film 80 on the STI structure 20 is removed. The inventor of the present invention could thereby successfully prevent the deterioration in the resistance of the NP junction or PN junction between the source/drain layer 70 and the semiconductor substrate 10 and suppress the standby leakage current.

1. A method for manufacturing a semiconductor device, comprising:
forming an isolation region on a semiconductor substrate;
forming an impurity diffusion layer in a region which includes an end of an active area adjacent to the isolation region;
depositing a metal film on the semiconductor substrate;
removing at least part of the metal film on the isolation region; and
subjecting the metal film and the semiconductor substrate to a heat treatment, thereby forming a silicide film on the impurity diffusion layer in a self-aligned fashion.

2. The method according to claim 1, wherein
the isolation region is formed into a lattice on a surface of the semiconductor substrate, and
if a ratio of an area of the active area to a chip area of the semiconductor device is less than 17.6%, the at least part of the metal film on the isolation region is removed after depositing the metal film.

3. The method according to claim 2, wherein
the semiconductor device is P-type MISFET.

4. The method according to claim 1, wherein
the isolation region is formed into stripes on a surface of the semiconductor substrate, and
if a ratio of an area of the active area to a chip area of the semiconductor device is less than 12%, the at least part of the metal film on the isolation region is removed after depositing the metal film.

5. The method according to claim 4, wherein
the semiconductor device is CMISFET including a P-type MISFET and N-type MISFET.

6. The method according to claim 1, wherein
the metal film includes any one of Ti (Titanium), Ni (Nickel), Co (Cobalt), Ta (Tantalum), Pd (Palladium) or Pt (Platinum).

7. The method according to claim 2, wherein
the metal film includes any one of Ti (Titanium), Ni (Nickel), Co (Cobalt), Ta (Tantalum), Pd (Palladium) or Pt (Platinum).

8. The method according to claim 3, wherein
the metal film includes any one of Ti (Titanium), Ni (Nickel), Co (Cobalt), Ta (Tantalum), Pd (Palladium) or Pt (Platinum).

9. The method according to claim 4, wherein
the metal film includes any one of Ti (Titanium), Ni (Nickel), Co (Cobalt), Ta (Tantalum), Pd (Palladium) or Pt (Platinum).

10. The method according to claim 5, wherein
the metal film includes any one of Ti (Titanium), Ni (Nickel), Co (Cobalt), Ta (Tantalum), Pd (Palladium) or Pt (Platinum).

11. A semiconductor device comprising:
a semiconductor substrate;
an isolation region formed into a lattice on a surface of the semiconductor substrate;
an active area adjacent to the isolation region and surrounded by the isolation region;
an impurity diffusion layer provided in a region which includes an end of the active area; and
a silicide film provided on the impurity diffusion layer, wherein
the suicide film on the end of the active area is equal in thickness to the silicide film in a central portion of the active area, and
a ratio of an area of the active area to a chip area of the semiconductor device is less than 17.6%.

12. The semiconductor device according to claim 11, wherein
the semiconductor device is P-type MISFET.

13. The semiconductor device according to claim 11, wherein
the metal film includes any one of Ti (Titanium), Ni (Nickel), Co (Cobalt), Ta (Tantalum), Pd (Palladium) or Pt (Platinum).

14. A semiconductor device comprising:
a semiconductor substrate;
an isolation region formed into stripes on a surface of the semiconductor substrate;
an active area adjacent to the isolation region;
an impurity diffusion layer provided in a region which includes an end of the active area; and
a silicide film provided on the impurity diffusion layer, wherein
the silicide film on the end of the active area is equal in thickness to the suicide film in a central portion of the active area, and
a ratio of an area of the active area to a chip area of the semiconductor device is less than 14%.

15. The semiconductor device according to claim 14, wherein
the semiconductor device is CMISFET including a P-type MISFET and N-type MISFET.

16. The semiconductor device according to claim 14, wherein
the metal film includes any one of Ti (Titanium), Ni (Nickel), Co (Cobalt), Ta (Tantalum), Pd (Palladium) or Pt (Platinum).
